(19) United States
(12) Patent Application Publication
(10) Pub. No.: US 2015/0340518 A1
(43) Pub. Date: Nov. 26, 2015

(54) PRINTABLE DIFFUSION BARRIERS FOR SILICON WAFERS

(71) Applicant: MERCK PATENT GMBH, Darmstadt (DE)

(72) Inventors: Ingo KOEHLER, Reinheim (DE); Oliver DOLL, Dietzenbach (DE); Sebastian BARTH, Darmstadt (DE)

(73) Assignee: MERCK PATENT GMBH, Darmstadt (DE)

(21) Appl. No.: 14/655,839

(22) PCT Filed: Dec. 18, 2013
(86) PCT No.: PCT/EP2013/003836

§ 371 Date: Jun. 26, 2015

(30) Foreign Application Priority Data
Dec. 28, 2012 (EP) 12008660.8
Dec. 10, 2013 (EP) 13005735.9

(51) Int. Cl. H01L 31/0224; C30B 29/06; H01L 31/06; C03C 3/04; H01L 31/028

(52) U.S. Cl. CPC H01L 31/02245; C03C 3/04; H01L 31/022458; H01L 31/028; H01L 31/06; H01L 31/022425; C30B 29/06

(57) ABSTRACT

The present invention relates to a novel process for the preparation of printable, high-viscosity oxide media, and to the use thereof in the production of solar cells.

The present invention relates to a novel process for the preparation of printable, low- to high-viscosity oxide media and to the use thereof in the production of solar cells, and to the products having an improved lifetime produced using these novel media.

The production of simple solar cells or solar cells which are currently represented with the greatest market share in the market comprises the essential production steps outlined below:

1. Saw-Damage Etching and Texture

A silicon wafer (monocrystalline, multicrystalline or quasi-monocrystalline, base doping p or n type) is freed from adherent saw damage by means of etching methods and “simultaneously” textured, generally in the same etching bath. Texturing is in this case taken to mean the creation of a preferentially aligned surface (nature) as a consequence of the etching step or simply the intentional, but not particularly aligned roughening of the wafer surface. As a consequence of the texturing, the surface of the wafer now acts as a diffuse reflector and thus reduces the directed reflection, which is dependent on the wavelength and on the angle of incidence, ultimately resulting in an increase in the absorbed proportion of the light incident on the surface and thus an increase in the conversion efficiency of the same cell.

The above-mentioned etch solutions for the treatment of the silicon wafers typically consist, in the case of monocrystalline wafers, of dilute potassium hydroxide solution to which isopropyl alcohol has been added as solvent. Other alcohols having a higher vapour pressure or a higher boiling point than isopropyl alcohol may also be added instead if this enables the desired etching result to be achieved. The desired etching result obtained is typically a morphology which is characterised by pyramids having a square base which are randomly arranged, or rather etched out of the original surface. The density, the height and thus the base area of the pyramids can be partly influenced by a suitable choice of the above-mentioned components of the etch solution, the etching temperature and the residence time of the wafers in the etching tank. The texturing of the monocrystalline wafers is typically carried out in the temperature range from 70-<90° C., where etching removal rates of up to 10 μm per wafer side can be achieved.

In the case of multicrystalline silicon wafers, the etch solution can consist of potassium hydroxide solution having a moderate concentration (10-15%). However, this etching technique is hardly still used in industrial practice. More frequently, an etch solution consisting of nitric acid, hydrofluoric acid and water is used. This etch solution can be modified by various additives, such as, for example, sulfuric acid, phosphoric acid, acetic acid, N-methyl-pyrrolidone and also surfactants, enabling, inter alia, wetting properties of the etch solution and also its etching rate to be specifically influenced. These acidic etch mixtures produce a morphology of nested etching trenches on the surface. The etching is typically carried out at temperatures in the range between 4° C. to <10° C., and the etching removal rate here is generally 4 μm to 6 μm.

Immediately after the texturing, the silicon wafers are cleaned intensively with water and treated with dilute hydrofluoric acid in order to remove the chemical oxide layer formed as a consequence of the preceding treatment steps and contaminants absorbed and adsorbed therein and also thereon, in preparation for the subsequent high-temperature treatment.

2. Diffusion and Doping

The wafers etched and cleaned in the preceding step (in this case p-type base doping) are treated with vapour consisting of phosphorus oxide at elevated temperatures, typically between 750° C. and <1000° C. During this operation, the wafers are exposed to a controlled atmosphere consisting of dried nitrogen, dried oxygen and phosphoryl chloride in a quartz tube in a tubular furnace. To this end, the wafers are introduced into the quartz tube at temperatures between 600 and 700° C. The gas mixture is transported through the quartz tube. During the transport of the gas mixture through the strongly warmed tube, the phosphoryl chloride decomposes to give a vapour consisting of phosphorus oxide (for example P2O5) and chlorine gas. The phosphorus oxide vapour precipitates, inter alia, on the wafer surfaces (coating). At the same time, the silicon surface is oxidised at these temperatures with formation of a thin oxide layer. The precipitated phosphorus oxide is embedded in this layer, causing mixed oxide of silicon dioxide and phosphorus oxide to form on the wafer surface. This mixed oxide is known as phosphosilicate glass (PSG). This PSG glass has different softening points and different diffusion constants with respect to the phosphorus oxide depending on the concentration of the phosphorus oxide present. The mixed oxide serves as diffusion source for the silicon wafer, where the phosphorus oxide diffuses in the course of the diffusion in the direction of the interface between PSG glass and silicon wafer, where it is reduced to phosphorus by reaction with the silicon on the wafer surface (silicothermally). The phosphorus formed in this way has a solubility in silicon which is orders of magnitude higher than in the glass matrix from which it has been formed and thus preferentially dissolves in the silicon owing to the very high segregation coefficient. After dissolution, the phosphorus diffuses in the silicon along the concentration gradient into the volume of the silicon. In this diffusion process, concentration gradients in the order of 105 form between typical surface concentrations of 1021 atoms/cm² and the base doping in the region of 1016 atoms/cm². The typical diffusion depth is 250 to 500 nm and is dependent on the diffusion temperature selected (for example 880° C.) and the total exposure duration (heating & coating phase & injection phase & cooling) of the wafers in the strongly warmed atmosphere. During the coating phase, a PSG layer forms which a typical manner has a layer thickness of 40 to 60 nm. The coating of the wafers with the PSG glass, during which diffusion into the volume of the silicon also already takes place, is followed by the injection phase. This can be decoupled from the coating phase, but is in practice generally coupled directly to the coating in terms of time and is therefore usually also carried out at the same temperature. The composition of the gas mixture here is adapted in such a way that the further supply of phosphoryl chloride is suppressed. During the injection, the surface of the silicon is oxidised further by the oxygen present in the gas mixture, causing a phosphorus oxide-depleted silicon dioxide layer which likewise comprises phosphorus oxide to be generated between the actual doping source, the highly phosphorus oxide-enriched PSG glass, and the silicon wafer. The growth of this layer is very much faster in relation to the mass flow of the dopant from the source (PSG glass), since the oxide growth is accelerated by the high surface doping of the wafer itself (acceleration by one to two orders of magnitude). This enables depletion or separation of the doping source to be achieved in a certain manner, permeation of which with phosphorus oxide diffusing on is influenced by the material flow, which is dependent on the temperature and thus the diffusion coefficient. In this way, the doping of the silicon can be controlled in certain limits. A typical diffusion duration consisting of coating phase and injection phase is, for example, 25 minutes. After this treatment, the tubular furnace is automatically cooled, and the wafers can be removed from the process tube at temperatures between 600° C. to 700° C.

In the case of boron doping of the wafers in the form of an n-type base doping, a different method is carried out, which will not be explained separately here. The doping in these cases is carried out, for example, with boron trichloride or boron tribromide. Depending on the choice of the composition of the gas atmosphere employed for the doping, the formation of a so-called boron skin on the wafers may be observed. This boron skin is dependent on various influencing factors: crucially the doping atmosphere, the temperature, the doping duration, the source concentration and the coupled (or linear-combined) parameters mentioned above.

In such diffusion processes, it goes without saying that the wafers used cannot contain any regions of preferred diffusion and doping (apart from those which are formed by inhomogeneous gas flows and resultant gas pockets of inhomogeneous composition) if the substrates have not previously been subjected to a corresponding pretreatment (for example structuring thereof with diffusion-inhibiting and/or suppressing layers and materials).

For completeness, it should also be pointed out here that there are also further diffusion and doping technologies which have become established to different extents in the production of crystalline solar cells based on silicon. Thus, mention may be made of
ion implantation,
doping promoted via the gas-phase deposition of mixed oxides, such as, for example, those of PSG and BSG (borosilicate glass), by means of APCVD, PECVD, MOCVD and LPCVD processes,
(co)sputtering of mixed oxides and/or ceramic materials and hard materials (for example boron nitride),
gas-phase deposition of the last two,
purely thermal gas-phase deposition starting from solid dopant sources (for example boron oxide and boron nitride) and
liquid-phase deposition of doping liquids (inks) and pastes.

The latter are frequently used in so-called inline doping, in which the corresponding pastes and inks are applied by means of suitable methods to the wafer side to be doped. After or also even during the application, the solvents present in the compositions employed for the doping are removed by temperature and/or vacuum treatment. This leaves the actual dopant on the wafer surface. Liquid doping sources which can be employed are, for example, dilute solutions of phosphoric or boric acid, and also sol-gel-based systems or also solutions of polymeric borazil compounds. Corresponding doping pastes are characterised virtually exclusively by the use of additional thickening polymers, and comprise dopants in suitable form. The evaporation of the solvents from the above-mentioned doping media is usually followed by treatment at high temperature, during which undesired and interfering additives, but ones which are necessary for the formulation, are either “burnt” and/or pyrolysed. The removal of solvents and the burning-out may, but do not have to, take place simultaneously. The coated substrates subsequently usually pass through a flow-through furnace at temperatures between 800° C. and 1000° C., where the temperatures may be slightly increased compared with gas-phase diffusion in the tubular furnace in order to shorten the passage time. The gas atmosphere prevailing in the flow-through furnace may differ in accordance with the requirements of the doping and may consist of dry nitrogen, dry air, a mixture of dry oxygen and dry nitrogen and/or, depending on the design of the furnace to be passed through, zones of one or other of the above-mentioned gas atmospheres. Further gas mixtures are conceivable, but currently do not have major importance industrially. A characteristic of inline diffusion is that the coating and injection of the dopant can in principle take place decoupled from one another.

3. Removal of the Dopant Source and Optional Edge Insulation

The wafers present after the doping are coated on both sides with more or less glass on both sides of the surface. More or less in this case refers to modifications which can be applied during the doping process: double-sided diffusion vs. quasi-single-sided diffusion promoted by back-to-back arrangement of two wafers in one location of the process boats used. The latter variant enables predominantly single-sided doping, but does not completely suppress diffusion on the back. In both cases, it is currently state of the art to remove the glasses present after the doping from the surfaces by means of etching in dilute hydrofluoric acid. To this end, the wafers are firstly re-loaded in batches into wet-process boats and with their aid dipped into a solution of dilute hydrofluoric acid, typically 2% to 5%, and left therein until either the surface has been completely freed from the glasses, or the process cycle duration, which represents a sum parameter of the requisite etching duration and the process automation by machine, has expired. The complete removal of the glasses can be established, for example, from the complete dewetting of the silicon wafer surface by the dilute aqueous hydrofluoric acid solution. The complete removal of a PSG glass is achieved within 210 seconds at room temperature under these process conditions, for example using 2% hydrofluoric acid solution. The etching of corresponding BSG glasses is slower and requires longer process times and possibly also higher concentrations of the hydrofluoric acid used. After the etching, the wafers are rinsed with water.

On the other hand, the etching of the glasses on the wafer surfaces can also be carried out in a horizontally operating process, in which the wafers are introduced in a constant flow into an etcher in which the wafers pass horizontally through the corresponding process tanks (inline machine). In this case, the wafers are conveyed on rollers either through the process tanks and the etch solutions present therein, or the etch media are transported onto the wafer surfaces by means of roller application. The typical residence time of the wafers during etching of the PSG is about 90 seconds, and the hydrofluoric acid used is somewhat more highly concentrated than in the case of the batch process in order to compensate for the shorter residence time as a consequence of an increased etching rate. The concentration of the hydrofluoric acid is typically 5%. The tank temperature may optionally additionally be slightly increased compared with room temperature (>25° C.<50° C.).

In the process outlined last, it has become established to carry out the so-called edge insulation sequentially at the same time, giving rise to a slightly modified process flow: edge insulation glass etching. The edge insulation is a process-engineering necessity which arises from the system-inherent characteristic of double-sided diffusion, also in the case of intentional single-sided back-to-back diffusion. A large-area parasitic p-n junction is present on the (later) back of the solar cell, which is, for process-engineering reasons, removed partially, but not completely, during the later processing. As a consequence of this, the front and back of the solar cell are short-circuited via a parasitic and residue p-n junction (tunnel contact), which reduces the conversion efficiency of the later solar cell. For removal of this junction, the wafers are passed on one side over an etch solution consisting of nitric acid and hydrofluoric acid. The etch solution may comprise, for example, sulfuric acid or phosphoric acid as secondary constituents. Alternatively, the etch solution is transported (conveyed) via rollers onto the back of the wafer. The etch removal rate typically achieved in this process is about 1 μm of silicon (including the glass layer present on the surface to be treated) at temperatures between 4° C. to 8° C. In this process, the glass layer still present on the opposite side of the wafer serves as mask, which provides a certain protection against etch encroachment on this side. This glass layer is subsequently removed with the aid of the glass etching already described.

In addition, the edge insulation can also be carried out with the aid of plasma etching processes. This plasma etching is then generally carried out before the glass etching. To this end, a plurality of wafers are stacked one on top of the other, and the outside edges are exposed to the plasma. The plasma is fed with fluorinated gases, for example tetrafluoromethane. The reactive species occurring on plasma decomposition of these gases etch the edges of the wafer. In general, the plasma etching is then followed by the glass etching.

4. Coating of the Front Side with an Antireflection Layer

After the etching of the glass and the optional edge insulation, the front side of the later solar cells is coated with an antireflection coating, which usually consists of amorphous and hydrogen-rich silicon nitride. Alternative anti-reflection coatings are conceivable. Possible coatings can be titanium dioxide, magnesium fluoride, tin dioxide and/or consist of corresponding stacked layers of silicon dioxide and silicon nitride. However, antireflection coatings having a different composition are also technically possible. The coating of the wafer surface with the above-mentioned silicon nitride essentially fulfils two functions: on the one hand the layer generates an electric field owing to the numerous incorporated positive charges, that can keep charge carriers in the silicon away from the surface and can considerably reduce the recombination rate of these charge carriers at the silicon surface (field-effect passivation), on the other hand this layer generates a reflection-reducing property, depending on its optical parameters, such as, for example, refractive index and layer thickness, which contributes to it being possible for more light to be coupled into the later solar cell. The two effects can increase the conversion efficiency of the solar cell. Typical properties of the layers currently used are: a layer thickness of ˜80 nm on use of exclusively the above-mentioned silicon nitride, which has a refractive index of about 2.05. The antireflection reduction is most clearly apparent in the light wavelength region of 600 nm. The directed and undirected reflection here exhibits a value of about 1% to 3% of the originally incident light (perpendicular incidence to the surface perpendicular of the silicon wafer).

The above-mentioned silicon nitride layers are currently generally deposited on the surface by means of the direct PECVD process. To this end, a plasma into which silane and ammonia are introduced is ignited an argon gas atmosphere. The silane and the ammonia are reacted in the plasma via ionic and free-radical reactions to give silicon nitride and at the same time deposited on the wafer surface. The properties of the layers can be adjusted and controlled, for example, via the individual gas flows of the reactants. The deposition of the above-mentioned silicon nitride layers can also be carried out with hydrogen as carrier gas and/or the reactants alone. Typical deposition temperatures are in the range between 300° C. to 400° C. Alternative deposition methods can be, for example, LPCVD and/or sputtering.

5. Production of the Front-Side Electrode Grid

After deposition of the antireflection layer, the front-side electrode is defined on the wafer surface coated with silicon nitride. In industrial practice, it has become established to produce the electrode with the aid of the screen-printing method using metallic sinter pastes. However, this is only one of many different possibilities for the production of the desired metal contacts.

In screen-printing metallisation, a paste which is highly enriched with silver particles (silver content≧80%) is generally used. The sum of the remaining constituents arises from the rheological assistants necessary for formulation of the paste, such as, for example, solvents, binders and thickeners. Furthermore, the silver paste comprises a special glass-frit mixture, usually oxides and mixed oxides based on silicon dioxide, borosilicate glass and also lead oxide and/or bismuth oxide. The glass frit essentially fulfils two functions: it serves on the one hand as adhesion promoter between the wafer surface and the mass of the silver particles to be sintered, on the other hand it is responsible for penetration of the silicon nitride top layer in order to facilitate direct ohmic contact with the underlying silicon. The penetration of the silicon nitride takes place via an etching process with subsequent diffusion of silver dissolved in the glass-frit matrix into the silicon surface, whereby the ohmic contact formation is achieved. In practice, the silver paste is deposited on the wafer surface by means of screen printing and subsequently dried at temperatures of about 200° C. to 300° C. for a few minutes. For completeness, it should be mentioned that double-printing processes are also used industrially, which enable a second electrode grid to be printed with accurate registration onto an electrode grid generated during the first printing step. The thickness of the silver metallisation is thus increased, which can have a positive influence on the conductivity in the electrode grid. During this drying, the solvents present in the paste are expelled from the paste. The printed wafer subsequently passes through a flow-through furnace. A furnace of this type generally has a plurality of heating zones which can be activated and temperature-controlled independently of one another. During passivation of the flow-through furnace, the wafers are heated to temperatures up to about 950° C. However, the individual wafer is generally only subjected to this peak temperature for a few seconds. During the remainder of the flow-through phase, the wafer has temperatures of 600° C. to 800° C. At these temperatures, organic accompanying substances present in the silver paste, such as, for example, binders, are burnt out, and the etching of the silicon nitride layer is initiated. During the short time interval of prevailing peak temperatures, the contact formation with the silicon takes place. The wafers are subsequently allowed to cool.

The contact formation process outlined briefly in this way is usually carried out simultaneously with the two remaining contact formations (cf. 6 and 7), which is why the term co-firing process is also used in this case.

The front-side electrode grid consists per se of thin fingers (typical number>=68) which have a width of typically 80 μm to 140 μm, and also busbars having widths in the range from 1.2 mm to 2.2 mm (depending on their number, typically two to three). The typical height of the printed silver elements is generally between 10 μm and 25 μm. The aspect ratio is rarely greater than 0.3.

6. Production of the Back Busbars

The back busbars are generally likewise applied and defined by means of screen-printing processes. To this end, a similar silver paste to that used for the front-side metallisation is used. This paste has a similar composition, but comprises an alloy of silver and aluminium in which the proportion of aluminium typically makes up 2%. In addition, this paste comprises a lower glass-frit content. The busbars, generally two units, are printed onto the back of the wafer by means of screen printing with a typical width of 4 mm and compacted and are sintered as already described under point 5.

7. Production of the Back Electrode

The back electrode is defined after the printing of the busbars. The electrode material consists of aluminium, which is why an aluminium-containing paste is printed onto the remaining free area of the wafer back by means of screen printing with an edge separation <1 mm for definition of the electrode. The paste is composed of ≧80% of aluminium. The remaining components are those which have already been mentioned under point 5 (such as, for example, solvents, binders, etc.). The aluminium paste is bonded to the wafer during the co-firing by the aluminium particles beginning to melt during the warming and silicon from the wafer dissolving in the molten aluminium. The melt mixture functions as dopant source and releases aluminium to the silicon (solubility limit: 0.016 atom percent), where the silicon is p⁺-doped as a consequence of this injection. During cooling of the wafer, a eutectic mixture of aluminium and silicon, which solidifies at 577° C. and has a composition having a mole fraction of 0.12 of Si, deposits, inter alia, on the wafer surface.

As a consequence of the injection of aluminium into the silicon, a highly doped p-type layer, which functions as a type of mirror (“electric mirror”) on parts of the free charge carriers in the silicon, forms on the back of the wafer. These charge carriers cannot overcome this potential wall and are thus kept away from the back wafer surface very efficiently, which is thus evident from an overall reduced recombination rate of charge carriers at this surface. This potential wall is generally referred to as back surface field.

The sequence of the process steps described under points 5, 6 and 7 can, but does not have to, correspond to the sequence outlined here. It is evident to the person skilled in the art that the sequence of the outlined process steps can in principle be carried out in any conceivable combination.

8. Optional Edge Insulation

If the edge insulation of the wafer has not already been carried out as described under point 3, this is typically carried out with the aid of laser-beam methods after the co-firing. To this end, a laser beam is directed at the front of the solar cell, and the front-side p-n junction is parted with the aid of the energy coupled in by this beam. Cut trenches having a depth of up to 15 μm are generated here as a consequence of the action of the laser. Silicon is removed from the treated site here via an ablation mechanism or thrown out of the laser trench. This laser trench typically has a width of 30 μm to 60 μm and is about 200 μm away from the edge of the solar cell.

After production, the solar cells are characterised and classified in individual performance categories in accordance with their individual performances.

The person skilled in the art is aware of solar-cell architectures with both n-type and also p-type base material. These solar cell types include PERT solar cells
PERC solar cells
PERL solar cells
PERT solar cells
MWT-PERT and MWT-PERL solar cells derived therefrom
bifacial solar cells
back surface contact cells
back surface contact cells with interdigital contacts.

The choice of alternative doping technologies, as an alternative to the gas-phase doping already described at the outset, generally cannot solve the problem of the production of regions with locally different doping on the silicon substrate. Alternative technologies which may be mentioned here are the deposition of doped glasses, or of amorphous mixed oxides, by means of PECVD and APCVD processes. Thermally induced doping of the silicon located under these glasses can easily be achieved from these glasses. However, in order to produce, for example, regions with locally different doping, these glasses must be etched by means of mask processes in order to prepare the corresponding structures out of these. To this end, structured diffusion barriers can be deposited on the silicon wafers prior to the deposition of the glasses in order thus to define the regions to be doped. A similar effect can be achieved with the aid of diffusion barriers if different doping levels are required on the front and back surface of a wafer. If the diffusion barrier consists of materials which are deposited by means of PVD and CVD processes, as is the case for conventional barrier materials consisting of silicon dioxide, silicon nitride or also, for example, silicon oxynitride, these have to be subjected to structuring in a subsequent process step in order to produce regions with different doping on a wafer surface.

### OBJECT OF THE PRESENT INVENTION

The doping technologies usually used in the industrial production of solar cells, namely by gas phase-promoted diffusion with reactive precursors, such as phosphoryl chloride and/or boron tribromide, do not enable local doping and/or locally different doping to be produced specifically on silicon wafers. On use of known doping technologies, the production of such structures is only possible through complex and expensive structuring of the substrates. During the structuring, various mask processes must be matched to one another, which makes the industrial mass production of such substrates very complex. For this reason, concepts for the production of solar cells which require such structuring have not been able to establish themselves to date. It is therefore the object of the present invention to provide a simple, inexpensive process for specific local doping on silicon wafers, and a medium which can be employed in this process, enabling these problems to be overcome.

### SUBJECT-MATTER OF THE PRESENT INVENTION

The subject-matter of the present invention is thus to provide suitable, inexpensive media by means of which protecting layers against undesired diffusion can be introduced in simple printing technologies.

It has now been found that printable, high-viscosity oxide media which are suitable for this purpose are prepared by carrying out an anhydrous sol-gel-based synthesis by condensation of
a. symmetrically and/or asymmetrically di- to tetrasubstituted alkoxysilanes and alkoxyalkylsilanes with
b. strong carboxylic acids
and preparing paste-form, high-viscosity media (pastes) by controlled gelling. These media can be converted into diffusion barriers after the printing onto corresponding surfaces.

The symmetrically and/or asymmetrically di- to tetrasubstituted alkoxysilanes and alkoxyalkylsilanes used for the condensation in the sol-gel synthesis may contain saturated or unsaturated, branched or unbranched, aliphatic, alicyclic or aromatic radicals, individually or various of these radicals, which may in turn be functionalised at any desired position of the alkoxide radical or alkyl radical by heteroatoms selected from the group O, N, S, Cl, Br.

In accordance with the invention, the anhydrous sol-gel synthesis for the preparation of the high-viscosity oxide media is carried out in the presence of strong carboxylic acids. These are preferably acids selected from the group formic acid, acetic acid, oxalic acid, trifluoroacetic acid, mono-, di- and trichloroacetic acid, glyoxalic acid, tartaric acid, maleic acid, malonic acid, pyruvic acid, malic acid, 2-oxoglutaric acid.

High-viscosity oxide media based on hybrid sols and/or gels which are particularly suitable for the desired purpose are obtained if they are prepared using alcoholates/esters, acetates, hydroxides or oxides of aluminium, germanium, zinc, tin, titanium, zirconium or lead, and mixtures thereof.

In order to prepare a printable, high-viscosity medium in the process according to the invention, the oxide medium is gelled to give a high-viscosity, approximately glass-like material, which is subsequently either re-dissolved by addition of a suitable solvent or solvent mixture or transformed into a sol state with the aid of high-shear mixing devices and converted into a homogeneous gel by partial or complete structure recovery (gelling). The composition can advantageously be formulated as a high-viscosity oxide medium without addition of thickeners. Furthermore, a stable mixture which is stable on storage for a time of at least three months can be prepared in this way.

The printable high-viscosity media have particularly good properties if “capping agents” selected from the group acetoxytrialkylsilanes, alkoxytrialkylsilanes, halotrialkylsilanes and derivatives thereof are added to the oxide media in order to improve the stability.

This process according to the invention gives oxide media which comprise binary or ternary systems from the group SiO₂—Al₂O₃ and/or mixtures of higher order which arise through the use of alcoholates/esters, acetates, hydroxides or oxides of aluminium, germanium, zinc, tin, titanium, zirconium or lead during the preparation. These printable high-viscosity oxide media are particularly suitable for the production of diffusion barriers in treatment processes of silicon wafers for photovoltaic, microelectronic, micromechanical and micro-optical applications. For this purpose, these media can be printed in a simple manner by spin or dip coating, drop casting, curtain or slot-dye coating, screen or flexographic printing, gravure, ink-jet or aerosol-jet printing, offset printing, microcontact printing, electrohydrodynamic dispensing, roller or spray coating, ultrasonic spray coating, pipe jetting, laser transfer printing, pad printing or rotary screen printing, but preferably by screen printing, and can thus be used for the production of PERC, PERL, PERT, IBC solar cells and others, where the solar cells can have further architecture features, such as MWT, EWT, selective emitter, selective front surface field, selective back surface field and bifaciality.

The oxide media are very suitable for the production of thin, dense glass layers which act as sodium and potassium diffusion barrier in LCD technology as a consequence of thermal treatment. In particular, they are suitable for the production of thin, dense glass layers on the cover glass of a display, consisting of doped SiO₂ and/or mixed oxides which can be derived on the above-mentioned possible hybrid sols, which prevent the diffusion of ions from the cover glass into the liquid-crystalline phase.

In the production of handling- and abrasion-resistant layers on silicon wafers, the oxide medium printed onto the surface of the silicon wafers is dried and compacted for vitrification in a temperature range between 50° C. and 950° C., preferably between 50° C. and 700° C., particularly preferably between 50° C. and 400° C., simultaneously or sequentially, using one or more heating steps to be carried out sequentially (heating by means of a step function) and/or a heating ramp, resulting in the formation of a handling- and abrasion-resistant layer having a thickness of up to 500 nm. It is of particular importance in this connection that the oxide media according to the invention can be printed onto hydrophilic and/or hydrophobic silicon surfaces and subsequently converted into diffusion barriers. For the production of diffusion barriers against phosphorus and boron diffusion on silicon wafers, silicon wafers are printed with the high-viscosity oxide media, and the printed-on layers are thermally compacted. It is furthermore possible to obtain hydrophobic silicon wafer surfaces after removal of the applied oxide media by etching the glass layers formed after the printing, drying and compaction and/or doping of the oxide media according to the invention by temperature treatment with an acid mixture comprising hydrofluoric acid and optionally phosphoric acid, where the etch mixture used comprises, as etchant, hydrofluoric acid in a concentration of 0.001 to 10% by weight or 0.001 to 10% by weight of hydrofluoric acid and 0.001 to 10% by weight of phosphoric acid in a mixture.

### DETAILED DESCRIPTION OF THE INVENTION

Experiments have shown that the problems described above can be solved by the preparation of printable, high-viscosity pastes, also called oxide media below, having a viscosity >500 mPas and the use thereof in a process for specific local doping and/or for the production of locally different doping on silicon wafers. Printable high-viscosity oxide media according to the invention can be prepared by condensing di- to tetrasubstituted alkoxysilanes with strong carboxylic acids in an anhydrous sol-gel-based synthesis and preparing high-viscosity media (pastes) by controlled gelling.

Particularly good process results are achieved if alkoxysilanes and alkoxyalkylsilanes which are symmetrically and asymmetrically di- to tetrasubstituted by alkoxysilanes are condensed with strong carboxylic acids in an anhydrous sol-gel-based synthesis and paste-form and high-viscosity printable pastes, which are printed on as diffusion barriers, are prepared by controlled gelling.

For the production of the diffusion barrier, the high-viscosity paste can be printed onto the surface of a wafer by means of screen printing, subsequently dried and then thermally compacted. This compaction of the material printed onto wafers is usually carried out in a temperature range of 50-950° C., but the drying and compaction can be carried out simultaneously under particular conditions on introduction into a conventional doping furnace at temperatures in the range from 500-700° C. The doping furnaces employed are usually horizontal tubular furnaces. In another embodiment of the present invention, the drying and compaction can be carried out in one process step.

The diffusion barriers produced in this way are oxide layers which, however, can serve not only as diffusion barriers, but also as etch barrier or also as so-called etch resist in the production of solar cells. During the production of solar cells, the printed and dried and optionally compacted paste acts as temporary etch barrier to wet-chemical etch baths containing hydrofluoric acid, and to the vapours thereof or vapour mixtures containing hydrofluoric acid, but also in plasma etching processes with fluorine-containing precursors or in reactive ion etching.

In order to carry out the described process according to the invention for the production of diffusion barriers, the symmetrically and/or asymmetrically di- to tetrasubstituted alkoxysilanes used may contain individual or different saturated or unsaturated, branched or unbranched, aliphatic, alicyclic or aromatic radicals, which may in turn be functionalised at any desired position of the alkoxide radical by heteroatoms selected from the group O, N, S, Cl, Br.

The condensation reaction is carried out, as stated above, in the presence of strong carboxylic acids.

Carboxylic acids are taken to mean organic acids of the general formula

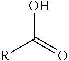

in which the chemical and physical properties are on the one hand clearly determined by the carboxyl group, since the carbonyl group (C═O) has a relatively strong electron-withdrawing effect, so that the bond of the proton in the hydroxyl group is strongly polarised, which can result in easy release thereof with liberation of H⁺ ions in the presence of a basic compound. The acidity of the carboxylic acids is higher if a substituent having an electron-withdrawing (−I effect) is present on the alpha-C atom, such as, for example, in corresponding halogenated acids or in dicarboxylic acids.

Accordingly, strong carboxylic acids which are particularly suitable for use in the process according to the invention are acids from the group formic acid, acetic acid, oxalic acid, trifluoroacetic acid, mono-, di- and trichloroacetic acid, glyoxalic acid, tartaric acid, maleic acid, malonic acid, pyruvic acid, malic acid and 2-oxoglutaric acid.

The process described enables the printable, high-viscosity oxide media to be prepared in the form of doping media based on hybrid sols and/or gels using alcoholates/esters, acetates, hydroxides or oxides of aluminium, gallium, germanium, zinc, tin, titanium, zirconium, arsenic or lead, and mixtures thereof.

In accordance with the invention, the oxide medium is gelled to give a high-viscosity material, and the resultant product is either re-dissolved by addition of a suitable solvent or solvent mixture or transformed into a sol state with the aid of high-shear mixing devices and allowed to recover to give a homogeneous gel as a consequence of partial or complete structure recovery (gelling).

The process according to the invention has proven particularly advantageous, in particular, through the fact that the high-viscosity oxide medium is formulated without addition of thickeners. In this way, a stable mixture which is stable on storage for a time of at least three months is prepared. If “capping agents” selected from the group acetoxytrialkylsilanes, alkoxytrialkylsilanes, halotrialkylsilanes and derivatives thereof are added to the oxide media during the preparation, this results in an improvement in the stability of the media obtained. The added “capping agents” need not necessarily be incorporated into the condensation and gelling reaction, but instead their time of addition may also be selected so that they can be stirred into the resultant paste material after gelling is complete, where the capping agent reacts chemically with reactive end groups, such as, for example, silanol groups, present in the network and thus prevents them from undergoing further condensation events which occur in an uncontrolled and undesired manner. The oxide media prepared in this way are particularly suitable for use as printable media for the production of diffusion barriers in the treatment of silicon wafers for photovoltaic, microelectronic, micromechanical and micro-optical applications.

The oxide media prepared in accordance with the invention can, depending on the consistency (depending on the rheological properties, such as, for example, the viscosity), be printed by spin or dip coating, drop casting, curtain or slot-dye coating, screen or flexographic printing, gravure, ink-jet or aerosol-jet printing, offset printing, microcontact printing, electrohydrodynamic dispensing, roller or spray coating, ultrasonic spray coating, pipe jetting, laser transfer printing, pad printing or rotary screen printing, where the printing is preferably carried out by means of screen printing.

Correspondingly prepared oxide media are particularly suitable for the production of PERC, PERL, PERT, IBC solar cells (BJBC or BCBJ) and others, where the solar cells have further architecture features, such as MWT, EWT, selective emitter, selective front surface field, selective back surface field and bifaciality, or for the production of thin, dense glass layers which act as sodium and potassium diffusion barrier in LCD technology as a consequence of thermal treatment, in particular for the production of thin, dense glass layers on the cover glass of a display, consisting of doped SiO₂, which prevent the diffusion of ions from the cover glass into the liquid-crystalline phase.

The present invention accordingly also relates to the novel oxide media prepared in accordance with the invention which have been prepared by the process described above and which comprise binary or ternary systems from the group SiO₂—Al₂O₃ and/or mixtures of higher order which arise through the use of alcoholates/esters, acetates, hydroxides or oxides of aluminium, germanium, zinc, tin, titanium, zirconium or lead during preparation. Addition of suitable masking agents, complexing agents and chelating agents in a sub- to fully stoichiometric ratio enables these hybrid sols on the one hand to be sterically stabilised and on the other hand to be specifically influenced and controlled with respect to their condensation and gelling rate, but also with respect to the rheological properties. Suitable masking agents and complexing agents as well as chelating agents are given in the patent applications WO 2012/119686 A, WO2012119685 A1 and WO2012119684 A. The contents of these specifications are therefore incorporated into the disclosure content of the present application.

By means of the oxide media obtained in this way, it is possible to produce a handling- and abrasion-resistant layer on silicon wafers. This result is achieved by printing the oxide medium onto hydrophilic wafers for the production of a diffusion barrier, where hydrophilic wafers are taken to mean those which are provided, for example, with an oxide film (wet-chemical, native oxide, PECVD, APCVD and/or, for example, thermal oxide). In addition, corresponding diffusion barriers can be produced in the same way on hydrophobic silicon wafer surfaces. Hydrophobic silicon wafer surfaces are taken to mean surfaces which are freed from oxides by a cleaning step with suitable ammonium fluoride or HF solutions and have hydrophobic properties owing to terminal H or F. However, these are also taken to mean wafer surfaces which have hydrophobic properties through the deposition of silane layers with a thickness of a few atoms (deposition in a hexamethyldisilazane (HMDS)-saturated atmosphere).

The diffusion barriers can be produced in a process in which the oxide medium which has been prepared in accordance with the invention and printed on the surface is dried and compacted for vitrification in a temperature range between 50° C. and 950° C., preferably between 50° C. and 700° C., particularly preferably between 50° C. and 400° C., simultaneously or sequentially, optionally using one or more heating steps to be carried out sequentially (heating by means of a step function) and/or a heating ramp, forming a handling- and abrasion-resistant layer having a thickness of up to 500 nm.

In generalised terms, this process for the production of handling- and abrasion-resistant layers can be characterised in that
a) silicon wafers are printed with the oxide media for the production of the desired diffusion barriers, the printed-on layer is dried, and optionally compacted, and the wafers coated in this way are subjected to subsequent diffusion with doping media, where the latter can be printable sol-gel-based oxidic doping materials, other printable doping inks and/or pastes, or APCVD and/or PECVD glasses provided with dopants, and also dopants from conventional gas-phase diffusion with phosphoryl chloride or boron tribromide or boron trichloride doping, causing doping of the wafer on the unprotected wafer side, while the protected side is not doped, or in that
b) after the doping described under a), the treated wafers are freed from residues of the dopants and the diffusion barrier on one side by means of etching, and the printable oxide media are subsequently printed as diffusion barrier over the entire surface of one side onto the wafer side opposite to that in step a), dried and optionally compacted, and the opposite wafer side which is now not protected by the diffusion barrier is subjected to further diffusion, where the doping media used satisfy the criteria indicated in a), or
c) silicon wafers are printed over the entire surface of one side with the printable oxide media, the oxide medium is dried and optionally compacted, and the opposite wafer side is coated with the same printable oxide medium using a structured print pattern, the oxide medium is dried and/or compacted, and the wafers coated in this way are subjected to subsequent diffusion with doping media, where the doping media used satisfy the criteria indicated in a), resulting in doping becoming established in the unprotected regions of the wafer, while the regions protected by printable oxide medium are not doped, or
d) in that the process indicated under point c) is carried out, where the treated wafers is freed from residues of the dopants and the diffusion barrier on one side by means of etching after the process procedure outlined, and the printable oxide media are subsequently printed onto the wafer side which has been doped in a structured manner in a complementary negative print pattern to that which was used under point c), dried and optionally compacted, and subsequent diffusion with doping media is subsequently carried out, where the doping media used satisfy the criteria indicated in a), resulting in doping becoming established in the unprotected regions of the wafer, while the regions protected by printable oxide medium are not doped, or
e) in that the process according to the invention is carried out as under d) before the process procedure described under point c) is used, or
f) in that silicon wafers are covered over the entire surface and/or in a structured manner with doping media indicated under point a), where the structuring of said doping media is achieved through the use of the printable, dried and optionally compacted oxide media according to the invention, and the deposited doping medium is subsequently covered over the entire surface and/or in a structured manner by means of the printable oxide media and is completely encapsulated after drying and optionally compaction of the oxide medium, or
g) in that silicon wafers are printed over the entire surface and/or in a structured manner with the printable oxide media in such a way that, as a consequence of controlled wet-film application and subsequent drying and optionally compaction thereof, a layer thickness of the diffusion barrier results which has a diffusion-inhibiting action on doping media deposited subsequently, where the doping media used satisfy the criteria indicated in a), and the dose of the dopant which is released to the substrate is thus controlled.

It has proven particularly advantageous that the layers produced in accordance with the invention, which are obtained by application of the high-viscosity sol-gel oxide media to silicon wafers and after thermal compaction thereof, act as diffusion barrier against phosphorus and boron diffusion.

In the process characterised in this way, it goes without saying that the doping media mentioned must be thermally activated and brought to diffusion. The activation can be carried out in various ways, such as, for example, by heating in furnaces, which are loaded batchwise or continuously with substrates, by irradiation of the substrate with laser radiation or with high-energy lamps, preferably halogen lamps.

For the formation of hydrophobic silicon wafer surfaces, the glass layers formed in this process after the printing of the oxide media according to the invention, drying and compaction thereof and/or doping by temperature treatment are etched with an acid mixture comprising hydrofluoric acid and optionally phosphoric acid, where the etch mixture used comprises, as etchant, hydrofluoric acid in a concentration of 0.001 to 10% by weight or may comprise 0.001 to 10% by weight of hydrofluoric acid and 0.001 to 10% by weight of phosphoric acid in a mixture.

The dried and compacted doping glasses can furthermore be removed from the wafer surface using the following etch mixtures: buffered hydrofluoric acid mixtures (BHF), buffered oxide etch mixtures, etch mixtures consisting of hydrofluoric and nitric acid, such as, for example, the so-called p-etches, R-etches, S-etches or etch mixtures, etch mixtures consisting of hydrofluoric and sulfuric acid, where the above-mentioned list makes no claim to completeness.

The binders added for the formulation of pastes are generally extremely difficult or even impossible to purify chemically or to free from their freight of metallic trace elements. The effort for their purification is high and, owing to the high costs, is out of proportion to the claim of the creation of an inexpensive and thus competitive, for example screen-printable, diffusion barrier for silicon wafers. These assistants thus to date represent a constant source of contamination by means of which undesired contamination of the treated substrates by contaminants in the form of metallic species present in the printing media is strongly favoured.

Surprisingly, these problems can be solved by the present invention described, more precisely by printable, viscous oxide media according to the invention, which can be prepared by a sol-gel process. In the course of the present invention, these oxide media can also be prepared as printable doping media by means of corresponding additives. A correspondingly adapted process and optimised synthesis approaches enable the preparation of printable oxide media
which have excellent storage stability,
which exhibit excellent printing performance with exclusion of agglutination and clumping on the screen,
which have an extremely low intrinsic contamination freight of metallic species and thus do not adversely affect the lifetime of the treated silicon wafers,
whose residues can be removed very easily from the surface of treated wafers after the thermal treatment, and
which, also due to this, do not make use of conventionally known thickeners, but instead can omit their use entirely.

The novel media can be synthesised on the basis of the sol-gel process and can be formulated further if this is necessary.

The synthesis of the sol and/or gel can be controlled specifically by addition of condensation initiators, such as, for example, a strong carboxylic acid, with exclusion of water. The viscosity can thus be controlled via the stoichiometry of the addition, for example of the carboxylic acid. In this way, addition of a super-stoichiometric amount enables the degree of crosslinking of the silica particles to be adjusted, enabling the formation of a highly swollen and printable network, i.e. a paste-form gel, which can be applied to surfaces, preferably onto silicon wafer surfaces, by means of various printing processes.

Suitable printing processes can be the following:

spin or dip coating, drop casting, curtain or slot-dye coating, screen or flexographic printing, gravure or ink-jet or aerosol-jet printing, offset printing, microcontact printing, electrohydrodynamic dispensing, roller or spray coating, ultrasonic spray coating, pipe jetting, laser transfer printing, pad printing and rotary screen printing. The printing is preferably carried out with the aid of screen printing.

The list given here is not definitive, and other printing processes may also be suitable.

Furthermore, the properties of the high-viscosity media according to the invention can be adjusted more specifically by addition of further additives, so that they are ideally suited for specific printing processes and for application to certain surfaces with which they may come into intense interaction. In this way, properties such as, for example, surface tension, viscosity, wetting behaviour, drying behaviour and adhesion capacity can be adjusted specifically. Depending on the requirements of the oxide media prepared, further additives may also be added. These may be:
surfactants, tensioactive compounds for influencing the wetting and drying behaviour,
antifoams and deaerating agents for influencing the drying behaviour,
further high- and low-boiling polar protic and aprotic solvents for influencing the particle-size distribution, the degree of precondensation, the condensation, wetting and drying behaviour as well as the printing behaviour,
further high- and low-boiling nonpolar solvents for influencing the particle-size distribution, the degree of precondensation, the condensation, wetting and drying behaviour and the printing behaviour,
particulate additives for influencing the rheological properties,
particulate additives (for example aluminium hydroxides and aluminium oxides, silicon dioxide) for influencing the dry-film thicknesses resulting after drying as well as the morphology thereof,
particulate additives (for example aluminium hydroxides and aluminium oxides, silicon dioxide) for influencing the scratch resistance of the dried films,
oxides, hydroxides, basic oxides, acetates, alkoxides, precondensed alkoxides of boron, gallium, silicon, germanium, zinc, tin, phosphorus, titanium, zirconium, yttrium, nickel, cobalt, iron, cerium, niobium, arsenic, lead and others for the formulation of hybrid sols.

In this connection, it goes without saying that each printing and coating method makes its own requirements of the composition to be printed. Typically, parameters which are to be set individually for the particular printing method are those such as the surface tension, the viscosity and the overall vapour pressure of the formulation arising.

Besides their use for the production of diffusion barriers, the printable media can be used as scratch-protection and corrosion-protection layers, for example in the production of components in the metal industry, preferably in the electronics industry, and in this case in particular in the manufacture of microelectronic, photovoltaic and microelectromechanical (MEMS) components. Photovoltaic components in this connection are taken to mean, in particular, solar cells and modules. Applications in the electronics industry are furthermore characterised by the use of the said pastes in the areas which are mentioned by way of example, but are not listed comprehensively: manufacture of thin-film solar cells from thin-film solar modules, production of organic solar cells, production of printed circuits and organic electronics, production of display elements based on technologies of thin-film transistors (TFTs), liquid-crystal displays (LCDs), organic light-emitting diodes (OLEDs) and touch-sensitive capacitive and resistive sensors.

The present description enables the person skilled in the art to apply the invention comprehensively. Even without further comments, it is therefore assumed that a person skilled in the art will be able to utilise the above description in the broadest scope.

If there is any lack of clarity, it goes without saying that the publications and patent literature cited should be consulted. Accordingly, these documents are regarded as part of the disclosure content of the present description.

For better understanding and in order to illustrate the invention, examples are given below which are within the scope of protection of the present invention. These examples also serve to illustrate possible variants. Owing to the general validity of the inventive principle described, however, the examples are not suitable for reducing the scope of protection of the present application to these alone.

Furthermore, it goes without saying to the person skilled in the art that, both in the examples given and also in the remainder of the description, the component amounts present in the compositions always only add up to 100% by weight, mol-% or % by vol., based on the entire composition, and cannot exceed this, even if higher values could arise from the percent ranges indicated. Unless indicated otherwise, % data are therefore regarded as % by weight, mol-% or % by vol.

The temperatures given in the examples and description as well as in the claims are always in ° C.

### EXAMPLES OF LOW-VISCOSITY DOPING MEDIA

### Example 1

51.4 g of L(+)-tartaric acid are weighed out into a round-bottomed flask, and 154 g of dipropylene glycol monomethyl ether and 25 g of tetraethyl orthosilicate are added. The reaction mixture is stirred at 90° C. for 90 h. During the warming, the tartaric acid dissolves completely within two hours, and a colourless and completely transparent solution forms. At the end of the reaction duration, the mixture gels completely, with formation of a transparent gel. The gel is subsequently homogenised in a mixer under the action of high shear, left to rest for one day and subsequently printed onto monocrystalline wafers polished on one side with the aid of a screen printer. To this end, the following screen and printing parameters are used: 280 mesh, 25 μm wire diameter (stainless steel), mounting angle 22.5°, 8-12 μm emulsion thickness over fabric. The separation is 1.1 mm, and the doctor-blade pressure is 1 bar. The print layout corresponds to a square having an edge length of 2 cm. After the printing, the wafers are dried on a hotplate at 300° C. for 2 minutes. A handling- and abrasion-resistant layer having interference colours forms. The layer can easily be etched and removed using dilute hydrofluoric acid (5%). After the etching, the previously printed surface is hydrophilic.

### Example 2

49.2 g of DL(+)-malic acid are weighed out into a round-bottomed flask, 80 g of dipropylene glycol monomethyl ether, 80 g of terpineol and 25.5 g of tetraethyl orthosilicate are added. The reaction mixture is stirred at 140° C. for 24 h. During the warming, the malic acid dissolves completely, and a slightly yellowish, slightly opaque mixture forms, which gels completely. The gel is subsequently homogenised in a mixer under the action of high shear, left to rest for one day and subsequently printed onto monocrystalline wafers polished on one side with the aid of a screen printer. To this end, the following screen and printing parameters are used: 280 mesh, 25 μm wire diameter (stainless steel), mounting angle 22.5°, 8-12 μm emulsion thickness over fabric. The separation is 1.1 mm, and the doctor-blade pressure is 1 bar. The print layout corresponds to a square having an edge length of 2 cm. After the printing, the wafers are dried on a hotplate at 300° C. for 2 minutes. A handling- and abrasion-resistant layer having interference colours forms. The layer can easily be etched and removed using dilute hydrofluoric acid (5%). After the etching, the previously printed surface is hydrophilic.

### Example 3

80 g of dipropylene glyco monomethyl ether, 40 g of diethylene glycol monoethyl ether, 40 g of terpineol, 23.5 g of tetraethyl orthosilicate and 19.2 g of pyruvic acid are weighed out in a round-bottomed flask and warmed to 90° C. with stirring. The mixture is left at this temperature for 72 h and subsequently warmed at 140° C. for 140 h. During the reaction, the mixture becomes an orange-yellow colour, and slight cloudiness occurs, but its intensity does not increase. The mixture gels completely and is subsequently homogenised in a mixer under the action of high shear and left to rest for one day.

### Example 4

40 g of diethylene glycol monoethyl ether, 40 g of diethylene glycol monobutyl ether, 40 g of terpineol, 12 g of tetraethyl orthosilicate and 20 g of glycolic acid are weighed out into a round-bottomed flask and warmed to 90° C. with stirring. The mixture is left at this temperature for 48 h, and 0.8 g of salicylic acid, 0.8 g of ethyl acetyl acetone and 1 g of pyrocatechol are subsequently added. When the masking agents have completely dissolved, 16.7 g of aluminium triisopropoxide are introduced into the reaction mixture with vigorous stirring. The mixture is left at this temperature for a further 30 minutes, allowed to cool slightly and subsequently treated in a rotary evaporator at 60° C., causing a weight loss of 18.5 g. The reaction mixture is allowed to cool to room temperature, during which gelling of the mixture commences.

The mixture is subsequently homogenised in a mixer under the action of high shear and left to rest for one day. The paste is printed with the aid of a screen printer onto silicon wafers polished on one side (p type, 525 μm thick). To this end, the following screen and printing parameters are used: mesh count 165 cm⁻¹, 27 μm thread diameter (polyester), mounting angle 22.5°, 8-12 μm emulsion thickness over fabric. The separation is 1.1 mm, and the doctor-blade pressure is 1 bar. The print layout corresponds to a square having an edge length of 2 cm. After the printing, the wafers are dried on a hotplate at 300° C. for 2 minutes (handling- and abrasion-resistant) and subsequently coated with a sol-gel-based phosphorus-containing doping ink by means of spraying from an atomiser bottle and subsequent spin coating at 2000 rpm for 30 s. The layer of doping ink is likewise dried on a hotplate at 300° C. for 2 minutes. The coated wafer is then treated in a muffle furnace at 900° C. for 10 minutes and subsequently freed from the vitrified layers by etching with dilute hydrofluoric acid. A sheet resistivity of on average 67 ohm/sqr is determined in the wafer regions which are not protected by the diffusion barrier using the four-point measurement station, while the sheet resistivity in the protected region is 145 ohm/sqr. The determination of the sheet resistivities of the above-described coatings on the opposite wafer surface is on average 142 ohm/sqr.

### Example 5

40 g of diethylene glycol monoethyl ether, 40 g of diethylene glycol monobutyl ether, 40 g of terpineol, 8 g of tetraethyl orthosilicate and 20 g of glycolic acid are weighed out into a round-bottomed flask and warmed to 90° C. with stirring. The mixture is left at this temperature for 48 h, and 0.8 g of salicylic acid, 0.8 g of ethyl acetyl acetone and 1 g of pyrocatechol are subsequently added. When the masking agents have completely dissolved, 16.7 g of aluminium triisopropoxide are introduced into the reaction mixture with vigorous stirring. The mixture is left at this temperature for a further 30 minutes, allowed to cool slightly and subsequently treated in a rotary evaporator at 60° C., causing a weight loss of 17 g. The reaction mixture is allowed to cool to room temperature, during which gelling of the mixture commences. The mixture is subsequently homogenised in a mixer under the action of high shear and left to rest for one day. The paste is printed with the aid of a screen printer onto silicon wafers polished on one side (p type, 525 μm thick). To this end, the following screen and printing parameters are used: mesh count 165 cm⁻¹, 27 μm thread diameter (polyester), mounting angle 22.5°, 8-12 μm emulsion thickness over fabric. The separation is 1.1 mm, and the doctor-blade pressure is 1 bar. The print layout corresponds to a square having an edge length of 2 cm. After the printing, the wafers are dried on a hotplate at 300° C. for 2 minutes (handling- and abrasion-resistant) and subsequently coated with a sol-gel-based phosphorus-containing doping ink by means of spraying from an atomiser bottle and subsequent spin coating at 2000 rpm for 30 s. The layer of doping ink is likewise dried on a hotplate at 300° C. for 2 minutes. The coated wafer is treated in a muffle furnace at 900° C. for 10 minutes and subsequently freed from the vitrified layers by etching with dilute hydrofluoric acid. Using the four-point measurement station, a sheet resistivity of on average 70 ohm/sqr is determined in the wafer regions which are not protected by the diffusion barrier, while the sheet resistivity in the protected region is 143 ohm/sqr. The determination of the sheet resistivities of the above-described coatings on the opposite wafer surface is on average 139 ohm/sqr.

1. Process for the preparation of printable, high-viscosity oxide media,
characterised in that an anhydrous sol-gel-based synthesis is carried out by condensation of
a. symmetrically and/or asymmetrically di- to tetrasubstituted alkoxysilanes and alkoxyalkylsilanes with
b. strong carboxylic acids,
and paste-form, high-viscosity media (pastes) are prepared by controlled gelling.

2. Process according to claim 1 for the preparation of printable oxide media, characterised in that an anhydrous sol-gel-based synthesis is carried out by condensation of
a. symmetrically and/or asymmetrically di- to tetrasubstituted alkoxysilanes and alkoxyalkylsilanes with
b. strong carboxylic acids,
and paste-form, high-viscosity printable media (pastes) which can be converted into diffusion barriers after the printing are prepared by controlled gelling.

3. Process according to claim 1, where the symmetrically and/or asymmetrically di- to tetrasubstituted alkoxysilanes and alkoxyalkylsilanes used contain saturated or unsaturated, branched or unbranched, aliphatic, alicyclic or aromatic radicals, individually or various of these radicals, which may in turn be functionalised at any desired position of the alkoxide radical or alkyl radical by heteroatoms selected from the group O, N, S, Cl, Br.

4. Process according to claim 1, characterised in that the strong carboxylic acids used are acids from the group formic acid, acetic acid, oxalic acid, trifluoroacetic acid, mono-, di- and trichloroacetic acid, glyoxalic acid, tartaric acid, maleic acid, malonic acid, pyruvic acid, malic acid, 2-oxoglutaric acid.

5. Process according to claim 1, characterised in that the printable oxide media are prepared on the basis of hybrid sols and/or gels, using alcoholates/esters, acetates, hydroxides or oxides of aluminium, germanium, zinc, tin, titanium, zirconium or lead, and mixtures thereof.

6. Process according to claim 1, characterised in that the oxide medium is gelled to give a high-viscosity, approximately glass-like material, and the product obtained is either re-dissolved by addition of a suitable solvent or solvent mixture or transformed into a sol state with the aid of high-shear mixing devices and converted into a homogeneous gel by partial or complete structure recovery (gelling).

7. Process according to claim 1, characterised in that the high-viscosity oxide medium is formulated without addition of thickeners.

8. Process according to claim 1, characterised in that a stable mixture which is stable on storage for a time of at least three months is prepared.

9. Process according to claim 1, characterised in that, in order to improve the stability, “capping agents” selected from the group acetoxytrialkylsilanes, alkoxytrialkylsilanes, halotrialkylsilanes and derivatives thereof are added to the oxide media.

10. Oxide media prepared by a process according to claim 1, which comprise binary or ternary systems from the group SiO₂—Al₂O₃ and/or mixtures of higher order which arise through the use of alcoholates/esters, acetates, hydroxides or oxides of aluminium, germanium, zinc, tin, titanium, zirconium or lead during the preparation.

11. Silicon wafers for photovoltaic, microelectronic, micromechanical and micro-optical applications, comprising oxide media according to claim 10.

12. PERC, PERL, PERT, IBC solar cells, where the solar cells have architecture features, such as MWT, EWT, selective emitter, selective front surface field, selective back surface field and bifaciality, comprising oxide media according to claim 10.

13. Thin, dense glass layers on the cover glass of a display, consisting of doped SiO₂, which prevent the diffusion of ions from the cover glass into the liquid-crystalline phase, comprising oxide media according to claim 10.

14. A handling- and abrasion-resistant layer on silicon wafers, characterised in that the oxide medium printed onto the surface of the silicon wafers is dried and compacted for vitrification in a temperature range between 50° C. and 950° C., preferably between 50° C. and 700° C., particularly preferably between 50° C. and 400° C., using one or more heating steps to be carried out sequentially (heating by means of a step function) and/or a heating ramp, resulting in the formation of a handling- and abrasion-resistant layer having a thickness of up to 500 nm, comprising oxide media according to claim 10.

15. diffusion barriers against phosphorus and boron diffusion on silicon wafers, characterised in that silicon wafers are printed with the high-viscosity oxide media, and the printed-on layers are thermally compacted, comprising oxide media according to claim 10.
